(19) United States
(12) Patent Application Publication
(10) Pub. No.: US 2026/0212936 A1
(43) Pub. Date: Jul. 23, 2026

(54) VOLTAGE GENERATING CIRCUIT

(71) Applicant: Winbond Electronics Corp., Taichung City (TW)

(72) Inventor: Ju-An Chiang, Hsinchu (TW)

(73) Assignee: Winbond Electronics Corp., Taichung City (TW)

(21) Appl. No.: 19/351,266

(22) Filed: Oct. 6, 2025

(30) Foreign Application Priority Data
Dec. 24, 2024 (TW) 113150301

(51) Int. Cl. G11C 16/30; G05F 1/575

(52) U.S. Cl. CPC G11C 16/30; G05F 1/575

(57) ABSTRACT

A voltage generating circuit including a comparator, a source follower circuit and an output circuit is provided. The comparator is configured to receive a feedback voltage and a reference voltage, and output a control signal according to a comparison result between the feedback voltage and the reference voltage. The source follower circuit is configured to be controlled by a control signal to adjust the feedback voltage output to the comparator so that the feedback voltage is equal to the reference voltage, and provide a drive voltage according to the feedback voltage. The output circuit operates between a power supply voltage and the reference voltage and is configured to generate a clamp voltage based on the drive voltage.

### CROSS-REFERENCE TO RELATED APPLICATION

This application claims the priority benefit of Taiwan application serial no. 113150301, filed on Dec. 24, 2024. The entirety of each of the above-mentioned patent applications is hereby incorporated by reference herein and made a part of this specification.

### BACKGROUND

### Technical Field

The invention relates to a voltage generating circuit, and in particular, to a voltage generating circuit suitable for semiconductor memory device.

### Description of Related Art

Flash memory provides long-term and large-scale data storage functions and has become an important data storage medium. For NAND flash memory, the bit lines need to be pre-charged during the memory operation of accessing page data. Therefore, how to stably provide the clamping voltage required for bit line pre-charging to the page buffer is one of the key points of concern for those skilled in the art.

### SUMMARY

The invention provides a voltage generating circuit, which can stably provide a clamp voltage required for pre-charging a bit line.

The voltage generating circuit of the invention includes a comparator, a source follower circuit and an output circuit. The comparator is configured to receive a feedback voltage and a reference voltage, and output a control signal according to a comparison result between the feedback voltage and the reference voltage. The source follower circuit is coupled to the comparator. The source follower circuit is configured to be controlled by a control signal to adjust the feedback voltage output to the comparator so that the feedback voltage is equal to the reference voltage, and provide a drive voltage according to the feedback voltage. The output circuit is coupled to the source follower circuit. The output circuit operates between a power supply voltage and the reference voltage, and is configured to generate a clamp voltage based on the drive voltage.

Based on above, the voltage generating circuit of the present invention can stably provide the clamp voltage required for bit line pre-charging and solve the problem of body effect at the same time.

In order to make the above-mentioned features and advantages of the present invention more obvious and easier to understand, embodiments are given below and are described in detail below with reference to the accompanying drawings.

### BRIEF DESCRIPTION OF THE DRAWINGS

FIG. 1 is a block diagram of a voltage generating circuit according to an embodiment of the present invention.

FIG. 2 is a schematic diagram of the voltage generating circuit of the embodiment of FIG. 1.

### DESCRIPTION OF THE EMBODIMENTS

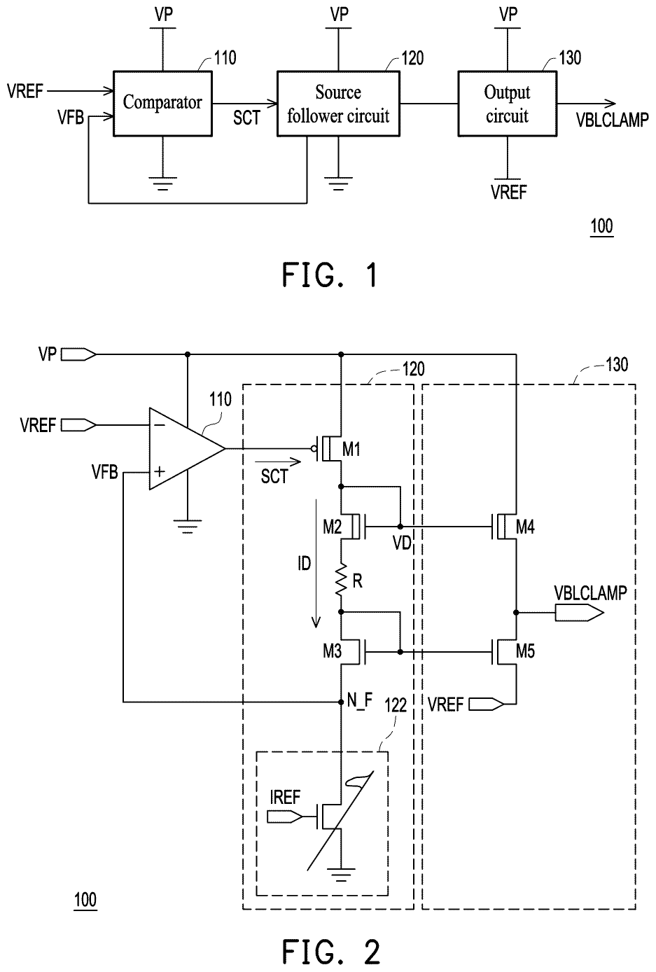

Referring to FIG. 1 and FIG. 2 at the same time, the voltage generating circuit 100 of the embodiment can be applied to semiconductor memory devices such as NAND flash memory, to provide a stable voltage for performing read operations, programming operations, and erasing operations, which includes a clamping voltage required for stably providing a bit line pre-charge to a page buffer. The voltage generating circuit 100 includes a comparator 110, a source follower circuit 120, and an output circuit 130.

The comparator 110 operates at the power supply voltage VP (such as about 6-8 volts), which can receive a feedback voltage VFB and a reference voltage VREF (such as about 0.5 volts), and compare the feedback voltage VFB with the reference voltage VREF. In details, as shown in FIG. 2, a non-inverting input terminal of the comparator 110 is coupled to the feedback node N_F of the source follower circuit 120 to receive the feedback voltage VFB, an inverting input terminal of the comparator 110 receives the reference voltage VREF. The comparator 110 can output a control signal SCT to the source follower circuit 120 at its output terminal according to the comparison result between the feedback voltage VFB and the reference voltage VREF.

The source follower circuit 120 is coupled to the comparator 110. The source follower circuit 120 operates at the power supply voltage VP and can be controlled by the control signal SCT to adjust the feedback voltage VFB output to the comparator 110 such that the feedback voltage VFB is equal to the reference voltage VREF. In details, the source follower circuit 120 includes a first transistor M1, a second transistor M2, a resistor R, a third transistor M3, and a current source circuit 122. The first terminal of the first transistor M1 receives the power supply voltage VP, and the control terminal receives the control signal SCT. The first terminal and the control terminal of the second transistor M2 are coupled to the second terminal of the first transistor M1 and provide a drive voltage VD. The first terminal of the resistor R is coupled to the second terminal of the second transistor M2. The first terminal and the control terminal of the third transistor M3 are coupled to the second terminal of the resistor R, and the second terminal of the third transistor M3 is coupled to the feedback node N_F. The current source circuit 122 is coupled between the feedback node N_F and a ground voltage (such as 0 volts).

The first transistor M1 is turned on by the control signal SCT. The first terminal and the control terminal of the second transistor M2 are coupled together, and the first terminal and the control terminal of the third transistor M3 are coupled together, and both are in a diode connection state. The source follower circuit 120 can form a feedback path through the feedback node N_F and the comparator 110. Therefore, the feedback voltage VFB may be continuously adjusted due to the feedback path. When entering steady state, the feedback voltage VFB may be equal to the reference voltage VREF.

The current source circuit 122 can receive a reference current IREF and generate a drive current ID flowing through the source follower circuit 120 according to the reference current IREF. The drive current ID of the embodiment is the current flowing from the first terminal of the first transistor M1 through the second transistor M2 and the third transistor M3 and transmitted to the current source circuit 122. For example, the current source circuit 122 can generate a plurality of weighted currents based on the reference current IREF in a binary weighted incremental manner. The current values of the weighted currents are respectively increased in the binary weighted incremental manner from low to high based on a mirror ratio of the transistors in the current source circuit 122. The current source circuit 122 selects a current to be summed from the weighted currents according to user's instruction to generate the drive current ID.

In addition, the source follower circuit 120 can provide the drive voltage VD at the control terminal of the second transistor M2 according to the feedback voltage VFB. Specifically, when the feedback voltage VFB is equal to the reference voltage VREF when entering the steady state, the voltages across the control terminals and the second terminals of the second transistor M2 to the fifth transistor M5 are equal to their respective threshold voltages. Therefore, the drive voltage VD generated at the control terminal of the second transistor M2 can be expressed by the following formula (1):

$$V D = V F B + VtnL + ID * R + VtnH \qquad ( 1 )$$

Where, VREF is the feedback voltage VFB at the feedback node N_F (equal to the reference voltage VREF), VtnL is the threshold voltage of the third transistor M3, ID is the current value of the drive current ID, R is the resistance value of the resistor R, and VtnH is the threshold voltage of the second transistor M2.

The output circuit 130 is coupled to the source follower circuit 120. The output circuit 130 operates between the power supply voltage VP and the reference voltage VREF. In details, the output circuit 130 includes a fourth transistor M4 and a fifth transistor M5. The first terminal of the fourth transistor M4 receives the power supply voltage VP, and the control terminal is coupled to the control terminal of the second transistor M2 to receive the drive voltage VD. The first terminal of the fifth transistor M5 is coupled to the second terminal of the fourth transistor M4, the control terminal of the fifth transistor M5 is coupled to the control terminal of the third transistor M3, and the second terminal of the fifth transistor M5 receives the reference voltage VREF.

The output circuit 130 can generate a clamp voltage VBLCLAMP at the second terminal of the fourth transistor M4 according to the drive voltage VD. Specifically, the threshold voltage of the fourth transistor M4 is equal to the threshold voltage (VtnH) of the second transistor M2. Therefore, the clamp voltage VBLCLAMP generated at the second terminal of the fourth transistor M4 can be expressed by the following formula (2):

$$VBLCLAMP = VD - VtnH = V F B + VtnL + ID * R \qquad ( 2 )$$

In this way, the output circuit 130 can stably provide the clamp voltage VBLCLAMP to the page buffer. The user can adjust the drive current ID by changing the reference current IREF or issuing instructions to the current source circuit 122, thereby allowing the output circuit 130 to generate the required clamp voltage VBLCLAMP. Besides, the voltage value of the reference voltage VREF of the embodiment can also be dynamically adjusted appropriately depending on the clamp voltage VBLCLAMP actually required, and is not a fixed value.

It should be noted that, in the embodiment, the first transistor M1 can be a P-type high voltage (HV) transistor, the second transistor M2 and the fourth transistor M4 can be an N-type HV transistor, and the third transistor M3 and the fifth transistor M5 can be an N-type low voltage (LV) transistor.

In addition, in design, the third transistor M3 and the fifth transistor M5 are designed to replicate bit line clamp transistors in the page buffer. The threshold voltage of the third transistor M3 and the fifth transistor M5 should be designed to match the threshold voltage of the bit line clamp transistor in the page buffer that receives the clamp voltage VBLCLAMP.

In the above circuit structure, since the voltage of the second terminal of the third transistor M3 and the fifth transistor M5 is the same (both are the reference voltage VREF), the body effect problem can be solved.

Since the source follower circuit 120 is incorporated into the feedback path, the drive voltage VD provided by the source follower circuit 120 and the clamp voltage VBLCLAMP generated according to the drive voltage VD can be more accurate, thereby improving the resistance to power supply noise.

Furthermore, the second terminal of the third transistor M3 and the fifth transistor M5, which are designed to replicate the bit line clamp transistor, is not a variable voltage, but a constant or temperature-compensated reference voltage VREF. The reference voltage VREF can depend on the pre-charged target voltage. As a result, the threshold voltage of the third transistor M3 and the fifth transistor M5 is more accurate and can more effectively replicate the bit line clamp transistors.

The current mirror formed by the source follower circuit 120 and the output circuit 130 uses LV transistors with higher accuracy, which facilitates the use of techniques to make the current mirror accurate. LV transistors are inherently better than HV transistors in terms of area, and N-type current mirrors are better than P-type current mirrors. Besides, to make the current mirror accurate, it is inevitable to use techniques such as cascode, which requires additional current to achieve, so it is more power-saving in low-voltage operation. Based on the above, the circuit structure area of the voltage generating circuit 100 of the embodiment of the present invention is smaller and more power-saving.

Furthermore, compared to using a voltage divider circuit composed of resistors, using the current source circuit 122 can also save the space occupied by resistors.

In summary, the voltage generating circuit of the present invention can stably provide the clamp voltage required for bit line pre-charging. In addition to solving the problem of the body effect, the design of the feedback path and the use of LV transistors can also be used to make the clamping voltage accurate.

What is claimed is:

1. A voltage generating circuit, comprising:
a comparator, configured to receive a feedback voltage and a reference voltage, and output a control signal according to a comparison result between the feedback voltage and the reference voltage;
a source follower circuit, coupled to the comparator, is configured to be controlled by the control signal to adjust the feedback voltage output to the comparator so that the feedback voltage is equal to the reference voltage, and provide a drive voltage according to the feedback voltage; and
an output circuit, coupled to the source follower circuit, operates between a power supply voltage and the reference voltage and is configured to generate a clamp voltage based on the drive voltage.

2. The voltage generating circuit according to claim 1, wherein the comparator and the source follower circuit operate at the power supply voltage.

3. The voltage generating circuit according to claim 1, wherein a non-inverting input terminal of the comparator is coupled to a feedback node in the source follower circuit to receive the feedback voltage, an inverting input terminal of the comparator receives the reference voltage, and an output terminal of the comparator outputs the control signal.

4. The voltage generating circuit according to claim 1, wherein the source follower circuit comprises:
a first transistor, its first terminal receives the power supply voltage, its control terminal receives the control signal;
a second transistor, its first terminal and control terminal are coupled to a second terminal of the first transistor;
a resistor, its first terminal is coupled to a second terminal of the second transistor; and
a third transistor, its first terminal and control terminal are coupled to a second terminal of the resistor, its second terminal is coupled to a feedback node.

5. The voltage generating circuit according to claim 4, wherein the source follower circuit provides the drive voltage at the control terminal of the second transistor according to the feedback voltage.

6. The voltage generating circuit according to claim 1, wherein the source follower circuit comprises:
a current source circuit, coupled between a feedback node and a ground voltage, generates a drive current flowing through the source follower circuit according to a reference current.

7. The voltage generating circuit according to claim 6, wherein the current source circuit generates a plurality of weighted currents in a binary weighted incremental manner based on the reference current.

8. The voltage generating circuit according to claim 7, wherein current values of the weighted currents are respectively increased in the binary weighted incremental manner from low to high based on a mirror ratio of the transistors in the current source circuit.

9. The voltage generating circuit according to claim 7, wherein the current source circuit selects a current to be summed from the weighted currents according to an instruction to generate the drive current.

10. The voltage generating circuit according to claim 4, wherein the first transistor is a P-type high voltage transistor, the second transistor is an N-type high voltage transistor, and the third transistor is an N-type low voltage transistor.

11. The voltage generating circuit according to claim 4, wherein the output circuit comprises:
a fourth transistor, its first terminal receives the power supply voltage, its control terminal is coupled to the control terminal of the second transistor to receive the drive voltage; and
a fifth transistor, its first terminal is coupled to a second terminal of the fourth transistor and generates the clamp voltage, its control terminal is coupled to the control terminal of the third transistor, its second terminal receives the reference voltage.

12. The voltage generating circuit according to claim 11, wherein a threshold voltage of the fourth transistor is equal to a threshold voltage of the second transistor.

13. The voltage generating circuit according to claim 11, wherein the fourth transistor is an N-type high voltage transistor, and the fifth transistor is an N-type low voltage transistor.

14. The voltage generating circuit according to claim 11, wherein a threshold voltage of the third transistor and a threshold voltage of the fifth transistor are designed to match a threshold voltage of a bit line clamp transistor in a page buffer receiving the clamp voltage.

15. The voltage generating circuit according to claim 11, wherein the voltage at the second terminal of the third transistor and the second terminal of the fifth transistor are both the reference voltage.

16. The voltage generating circuit according to claim 1, wherein a voltage value of the reference voltage is adjusted depending on the required clamp voltage.
